(19) United States
(12) Patent Application Publication
(10) Pub. No.: US 2010/0102379 A1
(43) Pub. Date: Apr. 29, 2010

(54) LATERAL DIFFUSED METAL OXIDE SEMICONDUCTOR DEVICE

(75) Inventors: Chang-Tzu Wang, Taipei City (TW); Tien-Hao Tang, Hsinchu City (TW)

Correspondence Address: J C PATENTS, 4 VENTURE, SUITE 250, IRVINE, CA, 92618, US

(73) Assignee: United Microelectronics Corp., Hsinchu (TW)

(21) Appl. No.: 12/260,329

(22) Filed: Oct. 29, 2008

(51) Int. Cl. H01L 47/00

(52) U.S. Cl. 257/328; 257/E47.001

(57) ABSTRACT

A LDMOS device includes a substrate of a first conductivity type, a deep well region of a second conductivity type, two body regions of the first conductivity type, a body connection region of the first conductivity type, two source regions of the second conductivity type, a drain region of the second conductivity type, a channel region, and a gate electrode. The body regions are disposed in the deep well region configured in the substrate. The body connection region is disposed in the deep well region to connect the body regions. Each of the source regions is disposed in the body region. The drain region is disposed in the deep well between the source regions. The channel region is disposed in a portion of the body region. The gate electrode is disposed on the deep well region between the source regions and the drain region and covers the channel region.

### BACKGROUND OF THE INVENTION

1. Field of Invention

The present invention is related to a semiconductor device; more specifically, the present invention is related a lateral double diffused metal oxide semiconductor device.

2. Description of Related Art

A lateral double diffused metal oxide semiconductor (LDMOS) device is commonly applied in an electrostatic discharge protection circuit in power source management. A LDMOS device is applied to prevent the damage induced on a semiconductor integrated circuit due to electrostatic discharge. More specifically, a LDMOS device is disposed between the internal device and each pad. When the internal device is a high voltage device, such as a large-sized output driver, the output driver is coupled to the control circuit, and the LDMOS device is gate grounded. Hence, a LDMOS device plays an important role in a typical power supply integrated circuit or in a smart power supply integrated circuit.

Generally speaking, a LDMOS device of an electrostatic discharge protection circuit includes a plurality of gates, a plurality of source electrodes and a plurality of drain electrodes, wherein the gates are multi-finger type, and the source electrodes and the drain electrodes are alternately configured at the two sides of the gates. Accordingly, the current selectively flows to these isolated source electrodes, resulting with a large current being delivered to certain source electrodes, while a small or even no current being delivered to other parts of the source electrodes. Hence, a LDMOS device is easily damage due to a local accumulation of current and the device characteristic of the LDMOS device is gravely affected.

### SUMMARY OF THE INVENTION

The present invention is to provide a lateral double diffused metal oxide semiconductor (LDMOS) device, wherein the amount of current flow through each of the source regions is substantially the same to provide the device with desirable characteristics.

The present invention is to provide a lateral double diffused metal oxide semiconductor (LDMOS) device that includes a substrate of a first conductive type, a deep well region of a second conductive type, two body regions of the first conductive type, a body connection region of the first conductive type, two source regions of the second conductive type, a drain region of the second conductive type, a channel region and a gate electrode. A deep well region is configured in the substrate. The plurality of the body regions is configured in the deep well region. The body connection region is configured in the deep well region for connecting the plurality of the body regions. The source regions are configured in the body regions. The drain region is configured in the deep well region between the plurality of the source regions. The channel region is configured in a portion of the body regions between the source regions and the drain region. The gate electrode is configured on the deep well region between the source regions and the drain region, and the gate electrode covers the channel region.

In accordance to an embodiment of the present invention, the dopant concentration of the aforementioned body connection region is substantially the same or greater than the dopant concentration of the body regions.

According to an embodiment of the invention, the above LDMOS device also includes a graded region of the second conductive type surrounding the peripheral of the drain region.

According to an embodiment of the invention, the aforementioned body regions includes first endpoints and second points, and the body connection region connects the first end point of each of the body regions.

According to an embodiment of the invention, the aforementioned body connection region includes two body connection regions, wherein one of the body connection regions connects the first endpoint of each of the body regions, while another one of the body connection regions connects the second endpoint of each of the body regions.

According to an embodiment of the invention, the above gate electrode is horseshoe shape or closed ring shape.

According to an embodiment of the invention, the first conductive type is P conductive type, and the second conductive type is N conductive type.

According to an embodiment of the invention, the first conductive type is N conductive type, and the second conductive type is P conductive type.

According to an embodiment of the invention, the aforementioned lateral double diffused metal oxide semiconductor device also includes a well region of the first conductive type and a doped region of the first conductive type. The well region is configured at the peripheral of the deep well region. The doped region serves as a protection ring and is configured in the well region.

The present invention also provides another lateral double diffused metal oxide semiconductor device that includes a substrate of a first conductive type, a deep well region of a second conductive type, a plurality of body regions of the first conductive type, a plurality of body connection regions of the first conductive type, a plurality of source regions of the second conductive type, a plurality of drain regions of the second conductive type, a plurality of channel regions and a plurality of gate electrodes. A deep well region is configured in the substrate. The plurality of the body regions is configured in the deep well region. The body connection regions serve as a protection ring and are configured in the deep well region. The source regions are configured in the body regions. The drain regions are configured in the deep well region between the source regions. The channel regions are configured in a part of the body regions between the neighboring source and drain regions. The gate electrodes are configured on the deep well region between the two neighboring source regions and the drain region configured in between the two neighboring source regions. The gate electrodes also cover the channel regions of two neighboring source regions.

In accordance to an embodiment of the present invention, the aforementioned body regions include a first body region, a second body region and a third body region, wherein the second body region is configured between the first body region and the third body region. Each body region includes a first end point, an intermediate section and a second endpoint, wherein the intermediate section is configured in between the first endpoint and the second endpoint. The body connection regions also include at least a first body connection region and at least a second body connection region, wherein the first body connection region connects the first body region with the second body region, and the second body connection region connects the second body region with the third body region.

According to an embodiment of the invention, the at least first body connection region connects one of, two of, or all of the first endpoints, the intermediate sections and the second endpoints of the first body region and the second body region, and the at least second body connection region connects one of, two of, or all of the first endpoints, the intermediate sections and the second endpoints of the second base body and the third base body.

In accordance to an embodiment of the present invention, the dopant concentration of the aforementioned body connection regions is substantially the same or greater than the dopant concentration of the body regions.

According to an embodiment of the invention, the above LDMOS device also includes a graded region of the second conductive type surrounding the peripheral of the drain region.

According to an embodiment of the invention, the above gate electrode is horseshoe shape or closed ring shape.

According to an embodiment of the invention, the first conductive type is P conductive type, and the second conductive type is N conductive type.

According to an embodiment of the invention, the first conductive type is N conductive type, and the second conductive type is P conductive type.

In accordance to the lateral double diffused metal oxide semiconductor device of the present invention, a body connection region is included to connect the body regions. The source regions in the body regions are electrically connected to each other. Hence, the amount of current flow through each of the source regions is substantially the same to greatly improve the electrical conduction condition of the lateral double diffused metal oxide semiconductor device and to improve the device characteristic of the lateral double diffused metal oxide semiconductor device.

In order to make the aforementioned and other objects, features and advantages of the present invention comprehensible, a preferred embodiment accompanied with figures is described in detail below.

### BRIEF DESCRIPTION OF THE DRAWINGS

FIG. 1A is a top view diagram of a lateral double diffused metal oxide semiconductor device according to an embodiment of the invention.

FIG. 1B is a schematic, cross-sectional diagram of FIG. 1A along the cutting line I-I′.

FIGS. 2 to 18 are top view diagrams of a lateral double diffused metal oxide semiconductor device according to an embodiment of the invention.

### DESCRIPTION OF EMBODIMENTS

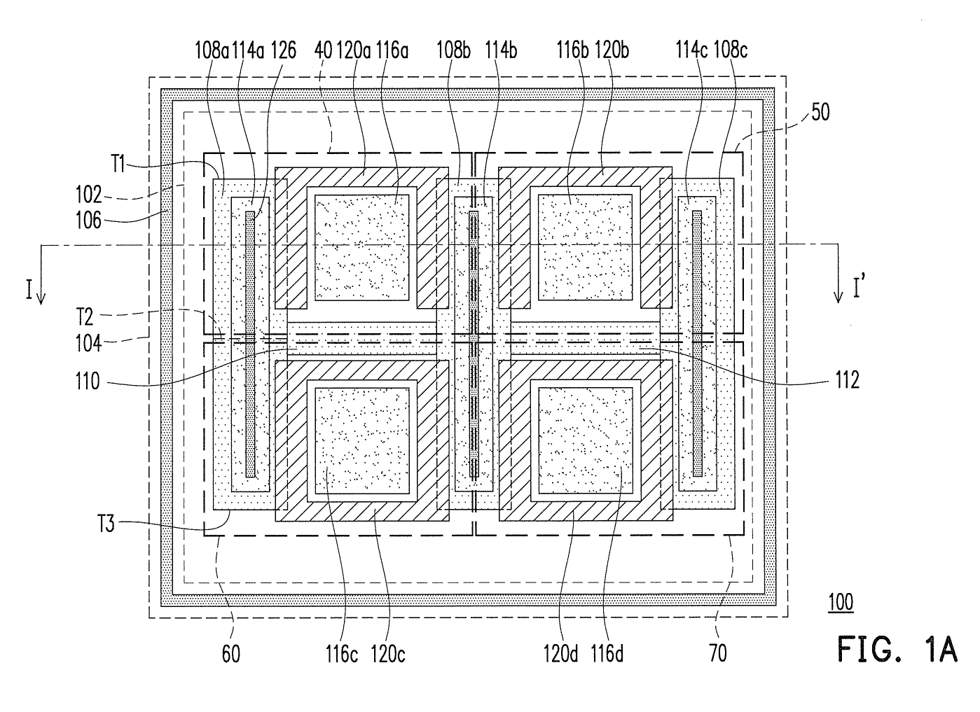

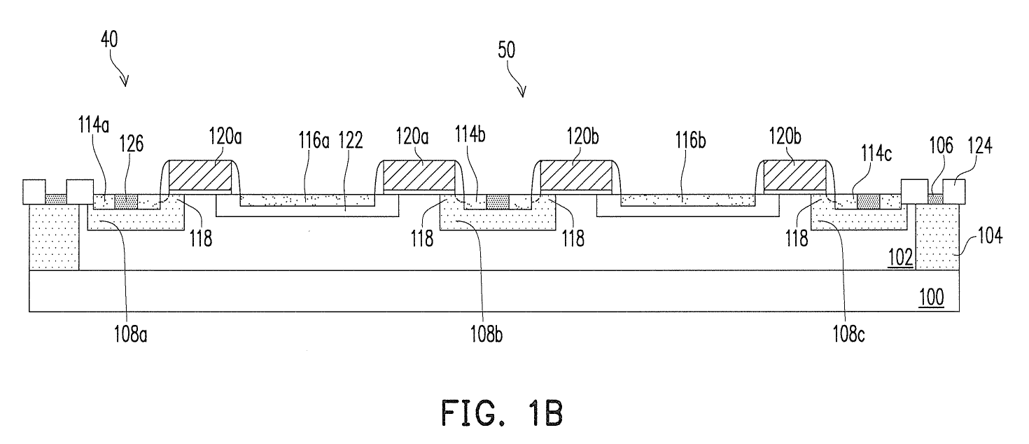

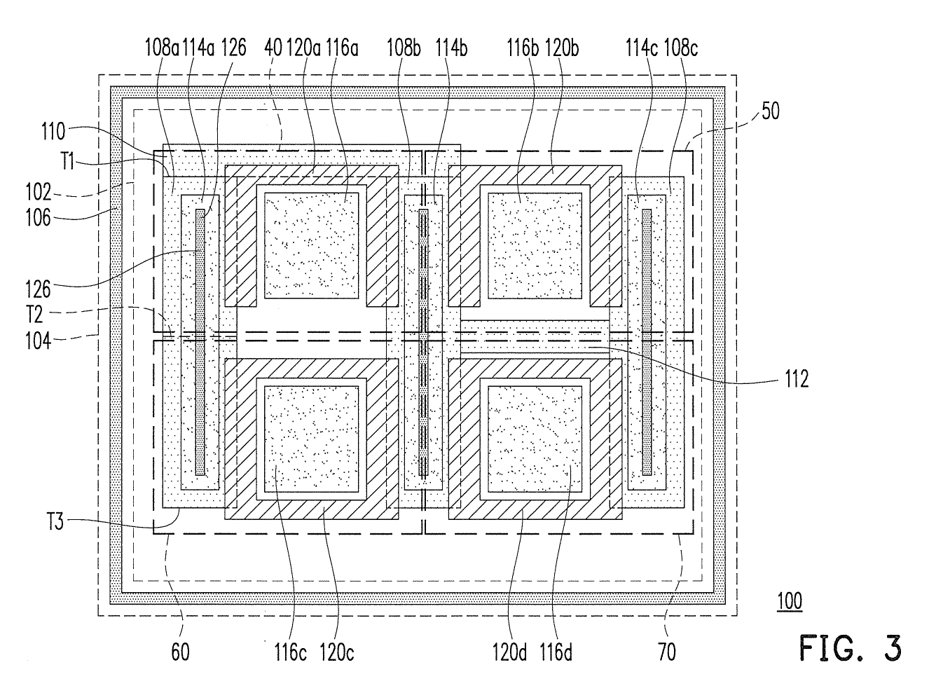

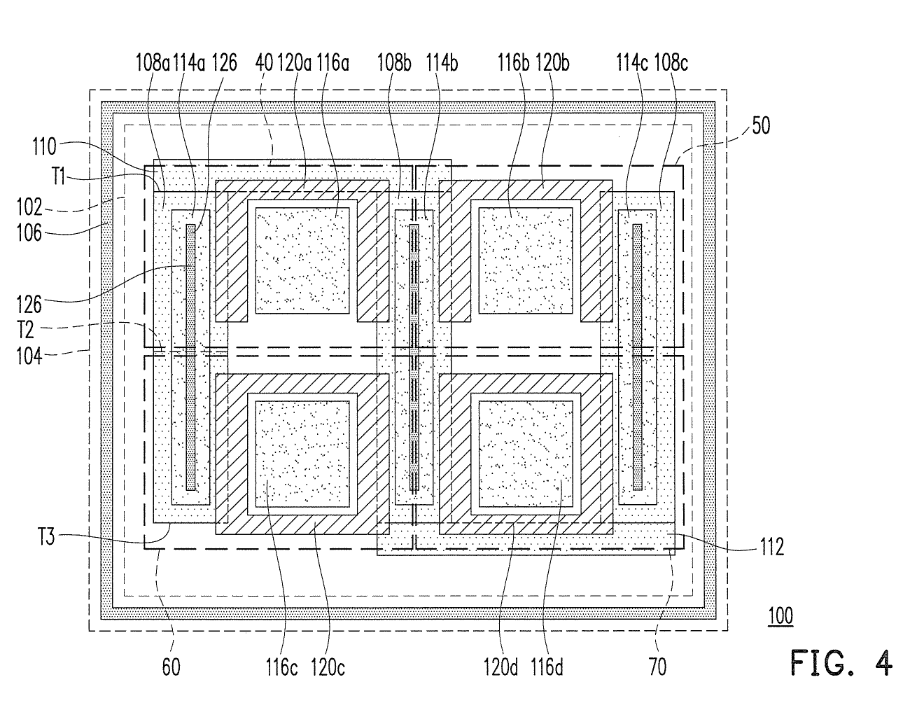

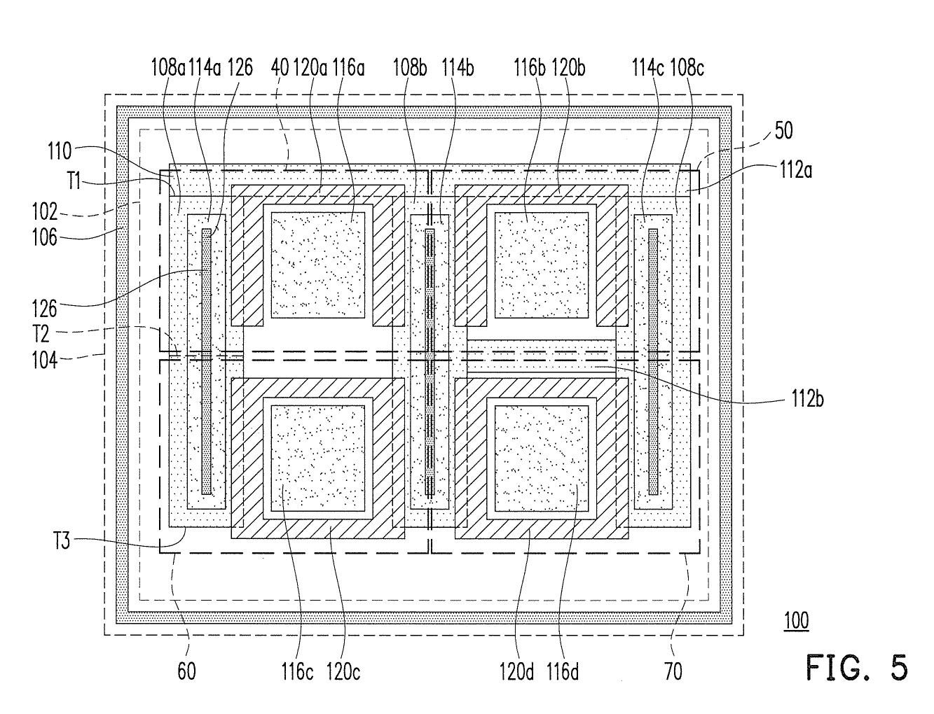

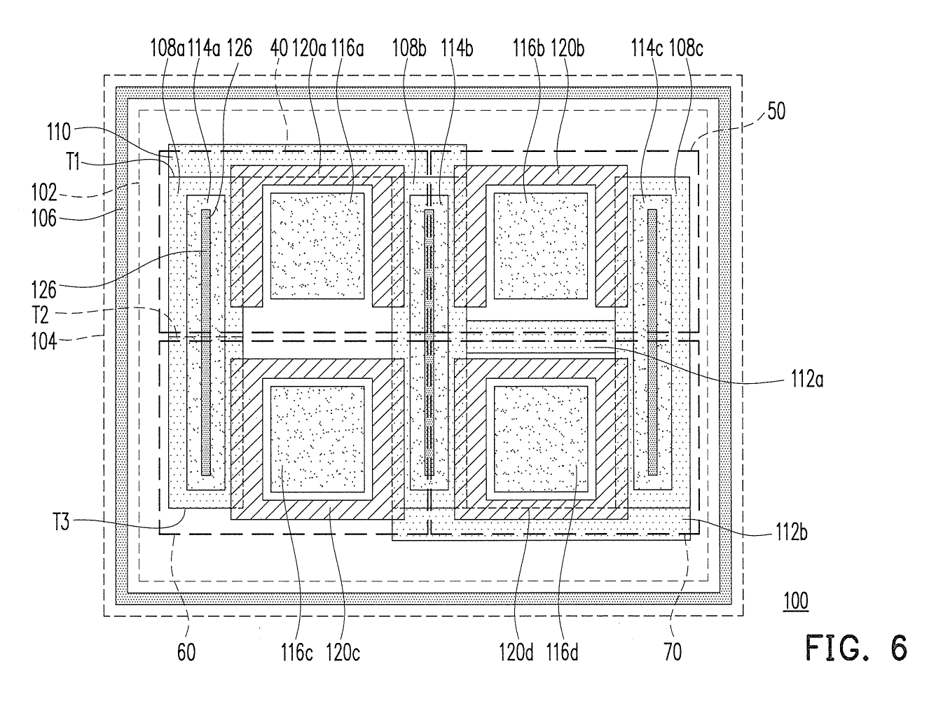

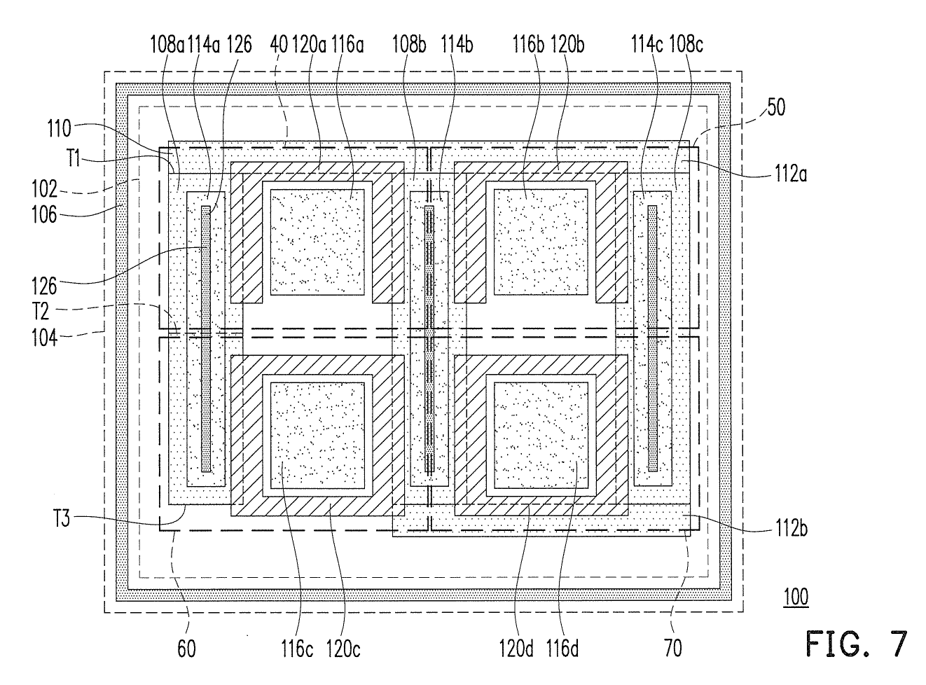

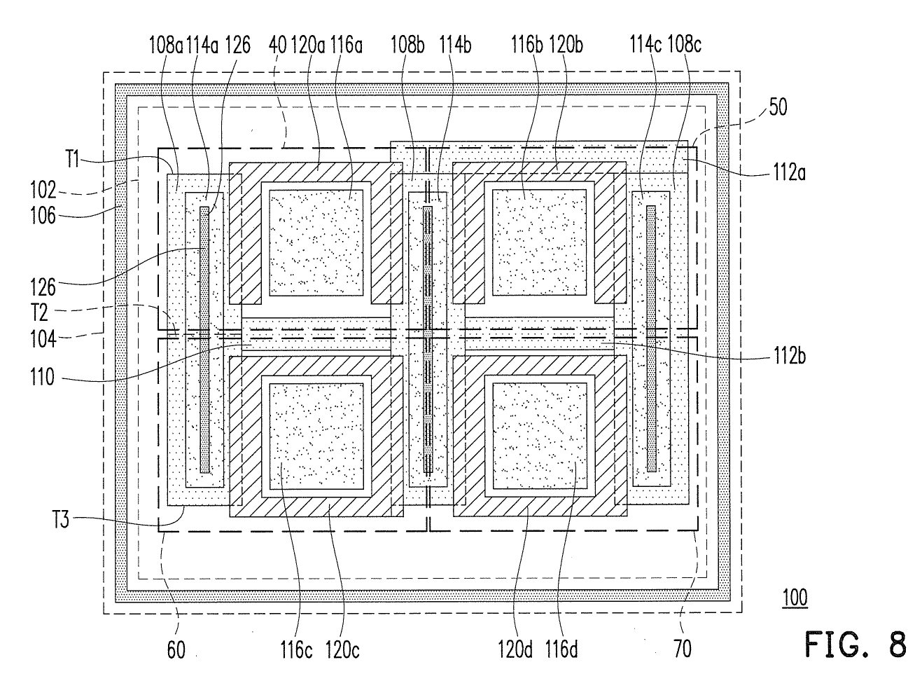

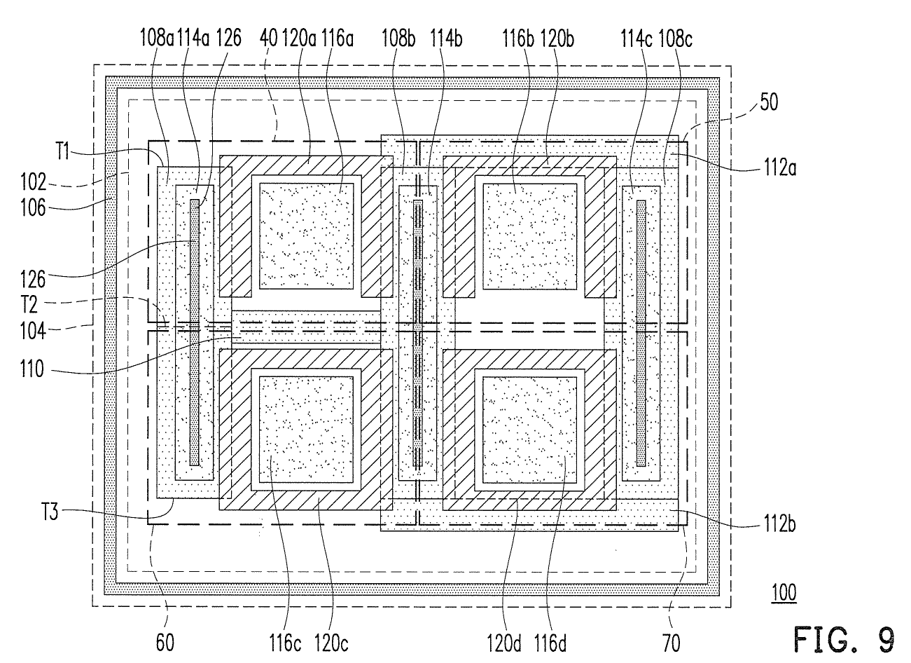

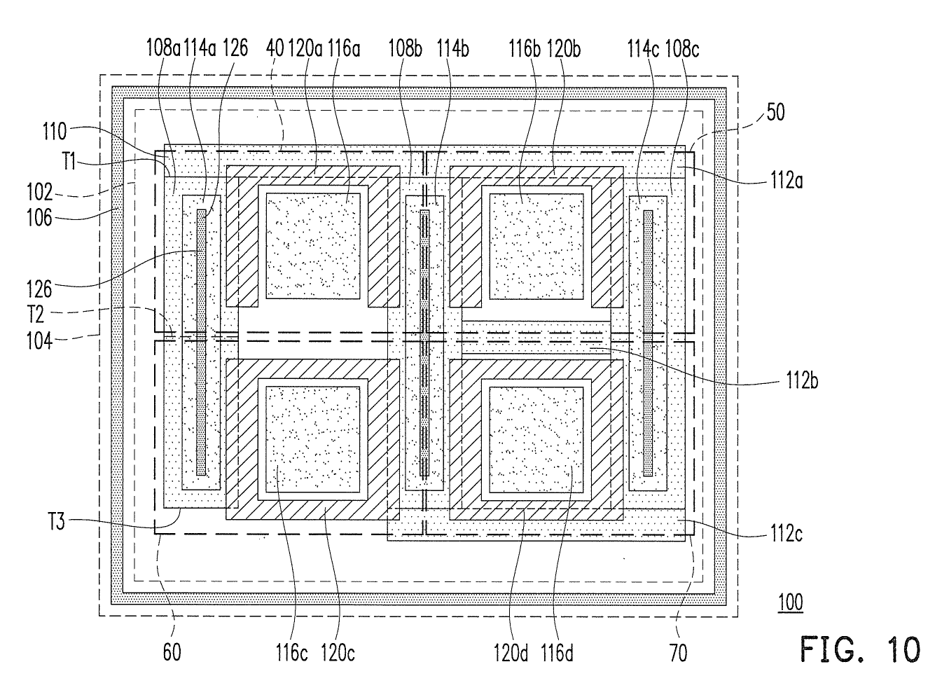

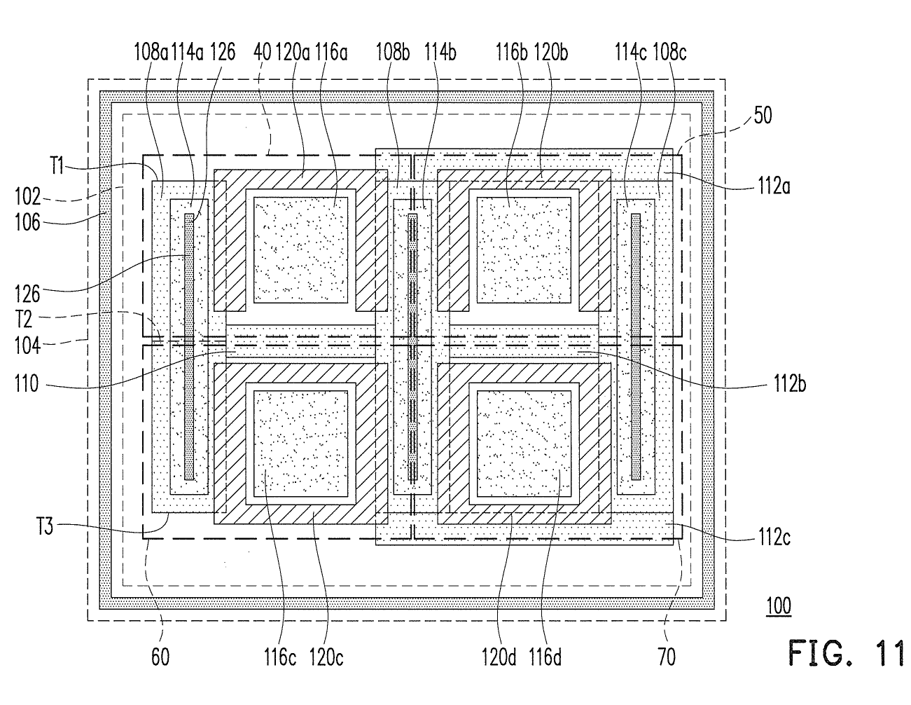

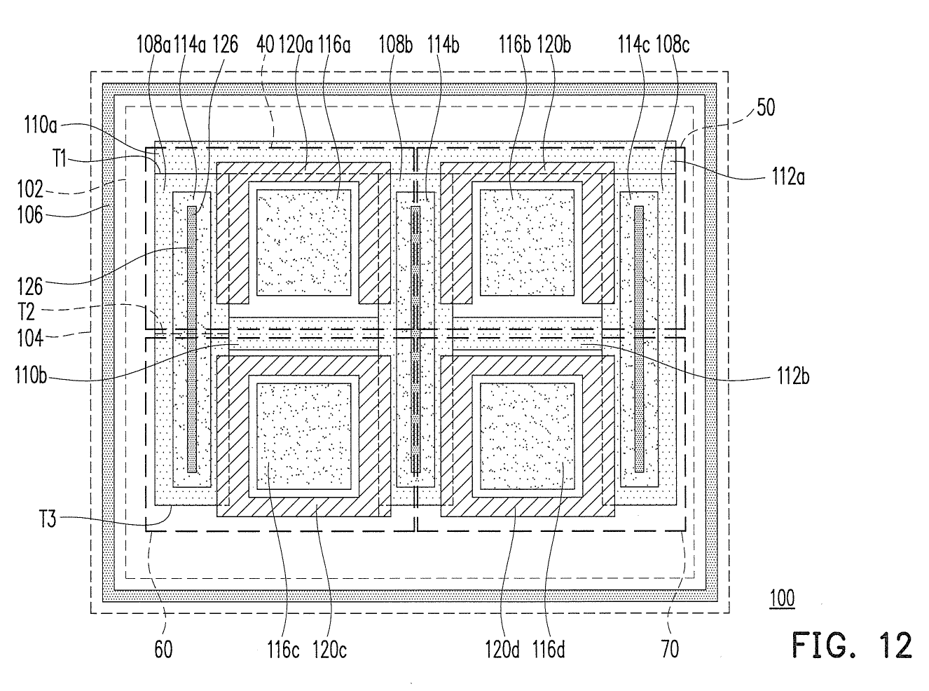

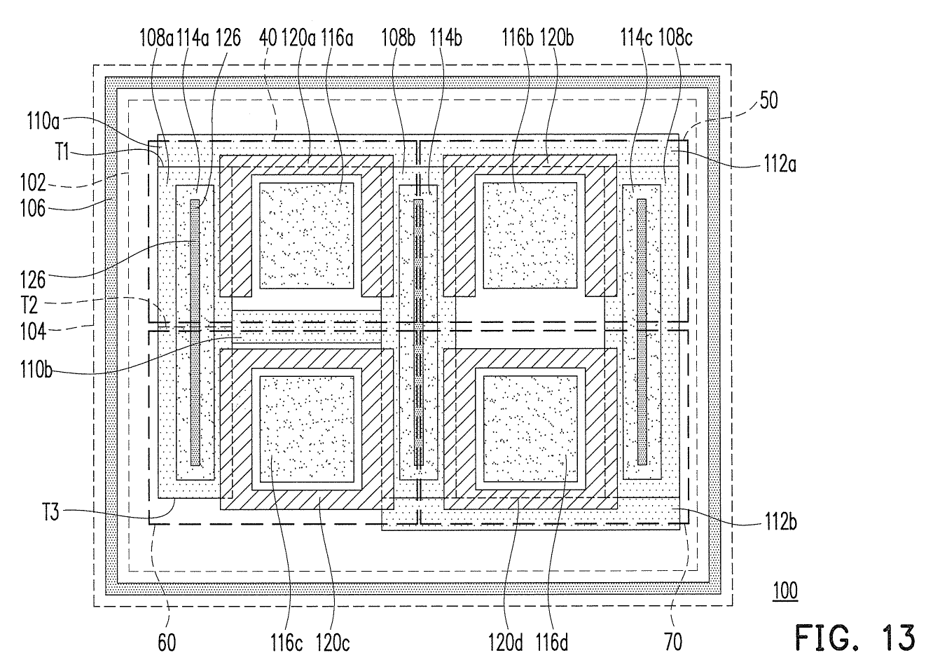

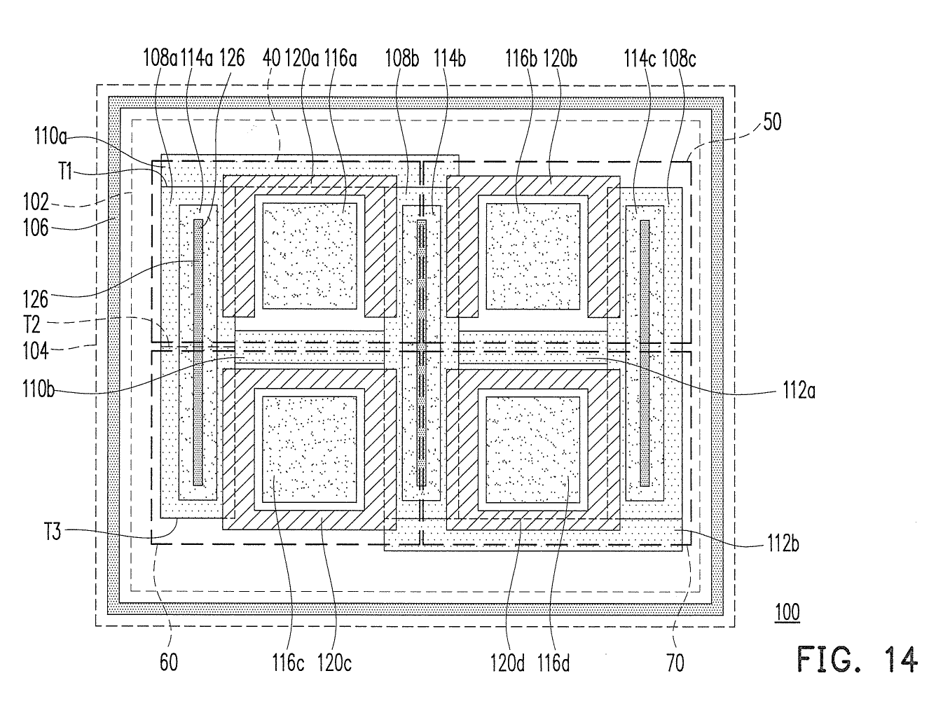

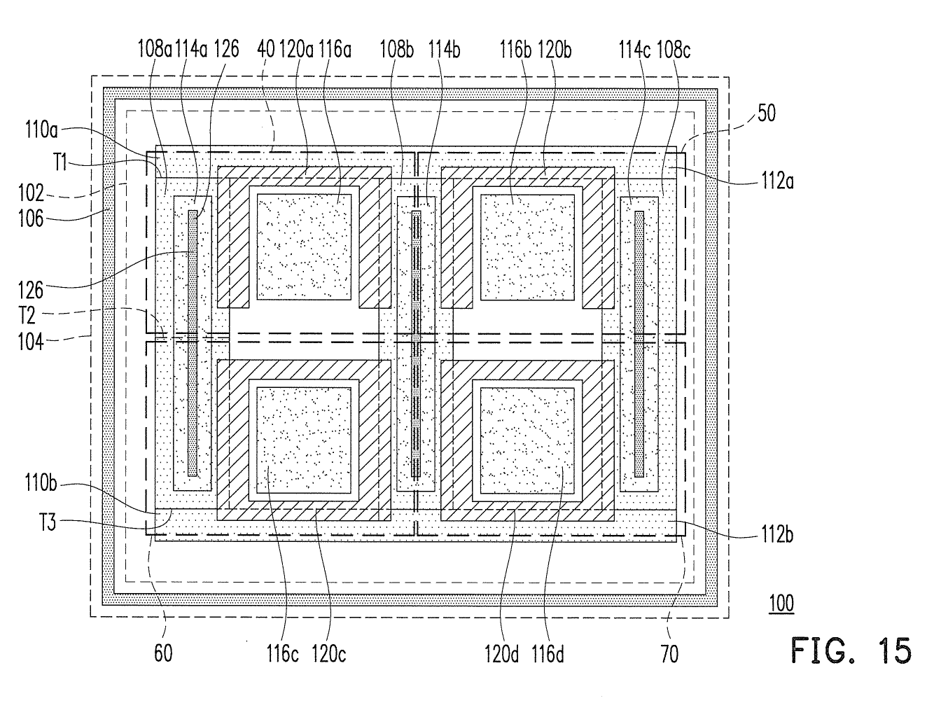

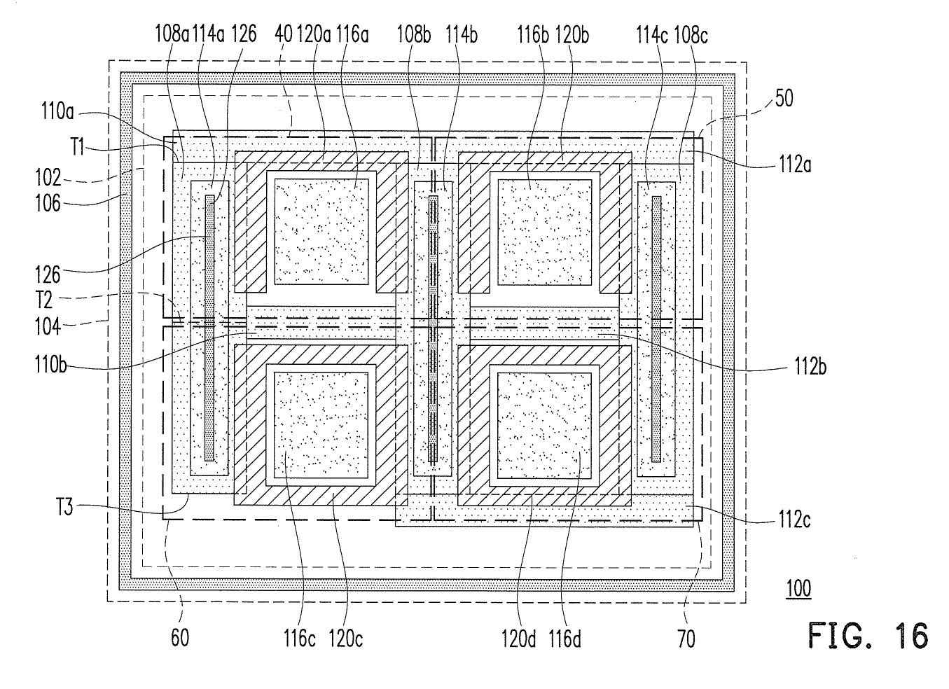

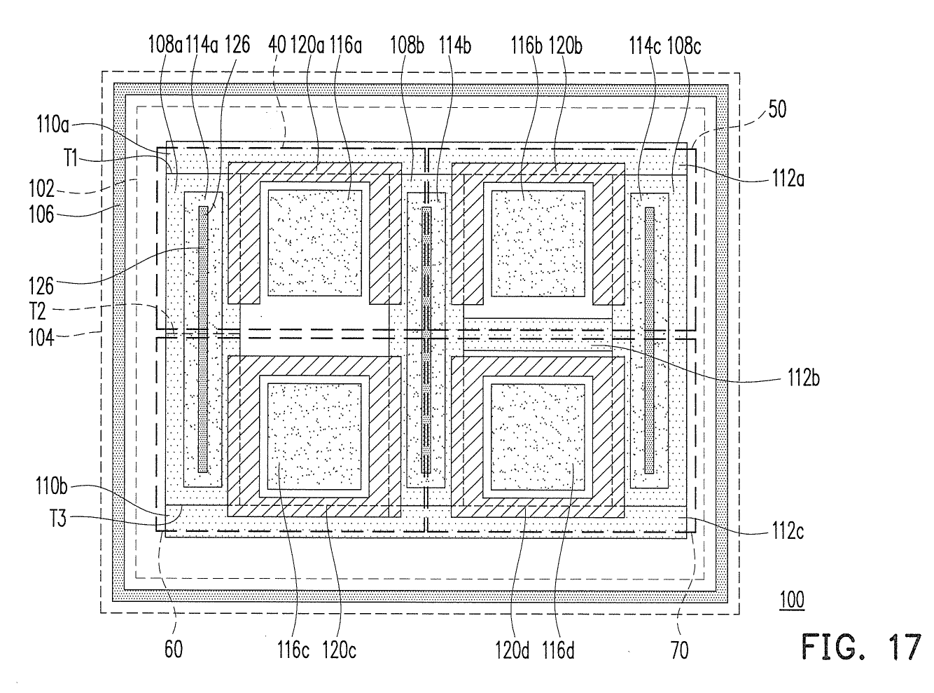

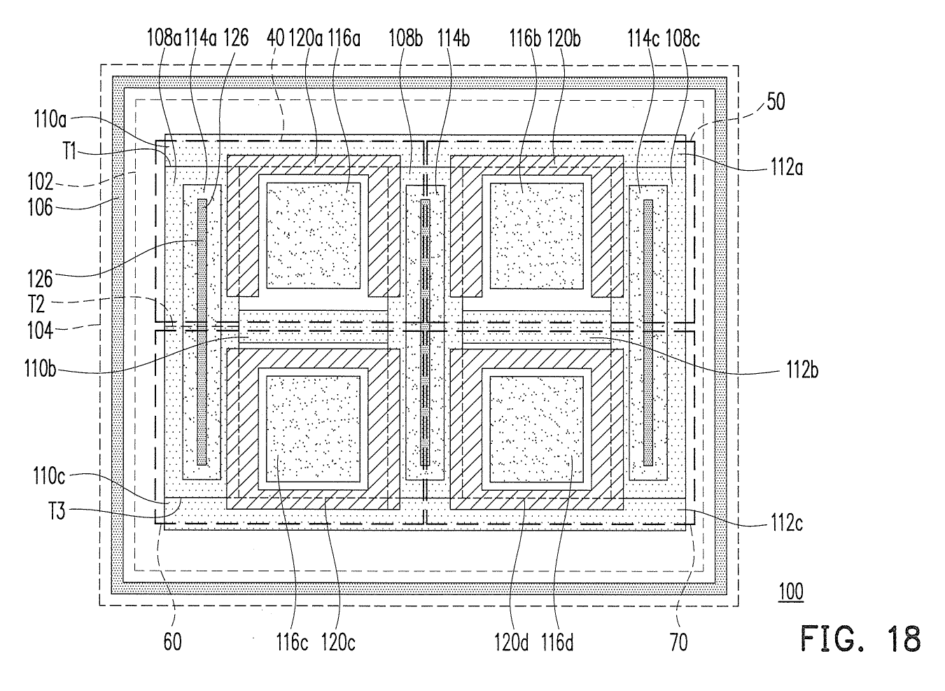

Reference will now be made in detail to the embodiments of the invention, examples of which are illustrated in the accompanying drawings. Whenever possible, the same reference numbers are used in the FIGS. 1 to 18 of the drawings and the description to refer to the same or like parts.

Referring to FIGS. 1A and 1B, wherein FIG. 1A is a top-view diagram of a lateral double diffused metal oxide semiconductor device according to one embodiment of the invention, and FIG. 1B is a cross-sectional view of FIG. 1A along the cutting line I-I′.

Referring to both FIGS. 1A and 1B, a lateral double diffused metal oxide semiconductor (LDMOS) device 40 includes a substrate 100 of a first conductive type, a deep well 102 of a second conductive type 102, two body regions 108a, 108b of the first conductive type, a body connection region 110 of the first conductive type, two source regions 114a, 114b of the second conductive type, a drain region 116a of the second conductive type 116a, a channel region 118 and gate electrode 120a. In an embodiment of the invention, the LDMOS device further includes a graded region 122 of a second conductive type and a doped region 126 of a first conductive type. The first conductive type may be P conductive type or N conductive type. When the first conductive type is N conductive type, the second conductive type is P conductive type. When the first conductive layer is P conductive type, the second conductive type is N conductive type. In this embodiment, P conductive type is represented as the first conductive type, and N conductive type is represented as the second conductive type.

In this embodiment of the invention, the substrate 100 is, for example, a P conductive type substrate, which can be a silicon substrate or other semiconductor material substrate. The deep well region 102 is, for example, an N conductive type deep well region, configured in the substrate 100. The body regions 108a, 108b, are, for example, P conductive type body regions, configured in the deep well region 102, wherein each of the body regions 108a 108b comprises an end point T1 and an end point T2. The source regions 114a, 114b are, for example, N conductive type, respectively disposed in the body regions 108a, 108b. The doped region 126, for example, a P conductive type doped region, is configured in the source regions 114a, 114b, respectively, wherein the dopant concentration of the doped region 126 is higher than those of the body regions 108a, 108b to serve as a pickup of the body regions 108a, 108b. The drain region 116 is, for example, N conductive type, and the drain region 116 is configured in the deep well region 102 between the source regions 114a, 114b. The graded region 122 is, for example, an N conductive type graded region, surrounding the peripheral of the drain region 116a. The channel regions 118 are configured in a portion of the body regions 108a, 108b between the neighboring source regions 114a, 114b and drain region 116a. The gate 120a is disposed above the deep well region 102 between neighboring two source regions 114a, 114b and the drain region 116a, and the gate 102a covers the channel region 118. In one embodiment, the gate 120 is, for example, horseshoe shape or closed ring shape (please refer to the gate 120c of the lateral double diffused metal oxide semiconductor device 60). A material of the gate 120 is, for example, polysilicon. The body regions 108a, 108b, the deep well region 102 and the substrate 100 constitute, for example, a pnp bipolar junction transistor (BJT).

Referring to FIG. 1A, the body connection region 110 of the lateral double diffused metal oxide semiconductor device 40 is, for example, a P conductive type body connection region, configured in the deep well region 102, and the body connection region 110 is for connecting the body region 108a and the body region 108b. In this embodiment of the invention, the body connection region 110 connects the end points T2 of the body region 108a and the body region 108b, for example. Accordingly, the source regions 114a, 114b configured in the body regions 108a, 108b are electrically connected to have uniform potential. Hence, the amount of current through each of the source regions 114a, 114b is substantially the same to prevent a localized accumulation of current at one particular source region or no current through another particular source region. Ultimately, the current conduction of the lateral diffusion metal oxide semiconductor device is greatly improved. In other aspects of the invention, the body connection region 110 may also connect the end points T1 of the body region 108a and the body region 108b, or the LDMOS device 40 includes two body connection regions, wherein one of the body connection regions connects the end points T1 of the body region 108 and the body region 108b, while another one of the body connection regions connects the end points T2 of the body region 108a and the body region 108b.

The above disclosure is directed to a single lateral double diffused metal oxide semiconductor device. However, the present invention is also applicable to a plurality of connected lateral double diffused metal oxide semiconductor devices configured in the protection ring.

Referring to FIGS. 1A and 1B, the LDMOS device of the current embodiment includes, in a doped region 106 of the protection ring, a substrate 100 of a first conductive type, a deep well region 102 of a second conductive type, a well region 104 of the first conductive type, the doped region 106 of the first conductive type, base bodies 108a, 108b, 108c of the first conductive type, a first body connection region 110 and a second body connection region 112 of the first conductive type, source regions 114a, 114b, 114c of the second conductive type, drain regions 116a, 116b, 116c, 116d of the second conductive type, gates 120a, 120b, 120c, 120d and a graded region 122 of the second conductive type. Further, an isolation structure 124, for example, a field oxide layer (FOX) structure or a shallow trench isolation (STI) structure, is configured at the peripheral of the doped region 106, covering a portion of the deep well region 102, the well region 104 and the substrate 100.

The aforementioned structure constitutes four lateral double diffused metal oxide semiconductor devices 40, 50, 60, 70. Although this aspect of the invention is directed to four lateral double diffused metal oxide semiconductor devices 40, 50, 60, 70 disposed in the protection ring, the present invention is limited as such. Since the relative relationships of the structural elements of the four lateral double diffused metal oxide semiconductor devices 50, 60, 70 are similar to those of the above-mentioned lateral double diffused metal oxide semiconductor devices 40, and a discussion thereof will not be presented herein.

In an embodiment of the invention, the lateral double diffused metal oxide semiconductor device 40 and the lateral double diffused metal oxide semiconductor device 50 commonly share the source region 114b, and commonly share the base body 108b. The lateral double diffused metal oxide semiconductor device 40 and the lateral double diffused metal oxide semiconductor device 60 commonly share the source regions 114a, 114b, commonly share the body regions 108a, 108b and commonly share the first body connection region 110. The lateral double diffused metal oxide semiconductor device 50 and the lateral double diffused metal oxide semiconductor device 70 commonly share the source regions 114b, 114c, commonly share the body regions 108b, 108b c, and commonly share the second body connection region 112. The structure of the second body connection region 112 is similar to that of the first body connection region 110 as disclosed above. More specifically, the body regions 108a, 108b, 108c comprise endpoints T1, intermediate sections T2 and endpoints T3, wherein the intermediate sections T2 is configured at a region between the endpoints T1 and the endpoints T3, but are not necessary configured at the centers of the body regions 108a, 108b, 108c. In this aspect of the invention, the first body connection region 110 connects the intermediate sections T2 of the body region 108a and the body region 108b, and the second body connection region 112 connects the intermediate sections T2 of the body region 108b and the body region 108c, for example. In other words, the first body connection region 110 and the second body connection region 112 connect the body regions 108a, 108b, 108c to each other to provide electrical connection among the source regions 114a, 114b, 114c in the body regions 108a, 108b, 108c and for the source regions 114a, 114b, 114c to have uniform potential. Consequently, the amount of current flow through each of the source regions 114a, 114b, 114c is substantially close to prevent a localized accumulation of current in a particular source region or no current flow through another particular source region. Hence, the current conduction in the lateral double diffused metal oxide semiconductor device is greatly improved.

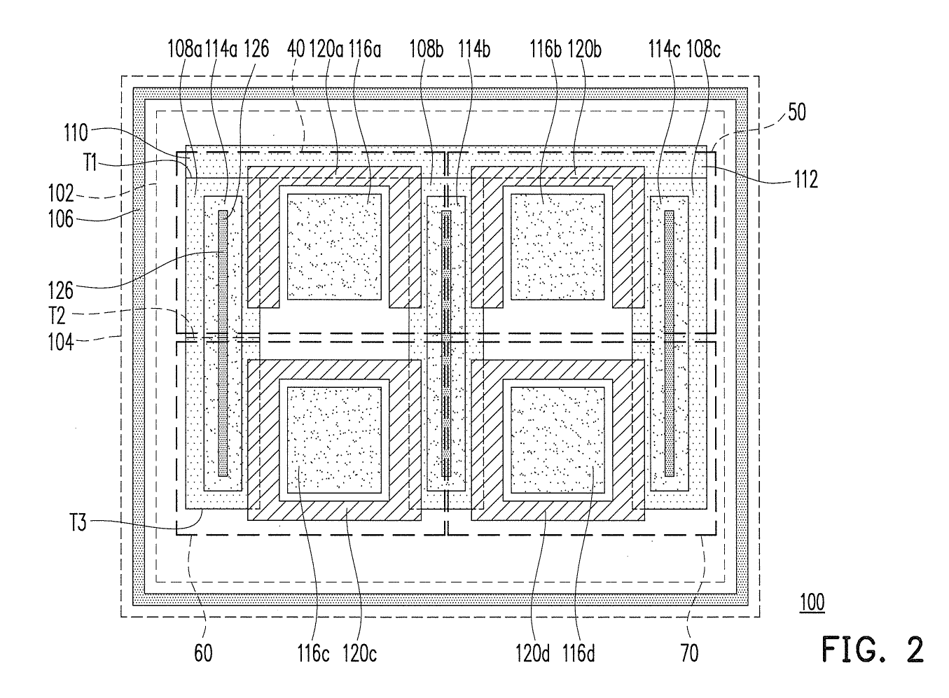

It is worth noting that the number of the first body connection region and the second body connection region of the invention is not particularly limited. In other embodiments, as shown in FIGS. 2 to 18, the first body connection regions 110, 110a, 110b, 110c can connect any one of, any two of, or all of the endpoints T1, the intermediate sections T2 and the endpoints T3 of the body regions 108a and 108b, while the second body connection region 112, 112a, 112b, 112c can connect any one of, any two of, or all of the endpoints T1, the intermediate sections T2 and the endpoints T3 of the body regions 108b and 108c. Hence, the body connection regions may have a variety of arrangements for connecting the body regions to each other.

In accordance to the above disclosures, the lateral double diffused metal oxide semiconductor (LDMOS) device of the present invention includes body connection regions to connect the body regions. Hence, the originally isolated source regions configured in each of the body regions become electrically connected, and the amount of current flow through each source region is about the same to mitigate the localized current accumulation condition. The device characteristic of the LDMOS device and the electrostatic discharge protection capability are improved. Further, the body connection regions are constructed by forming doped deep well regions. Accordingly, the fabrication method of the LDMOS device of the present invention is simple and is easily integrated with the existing fabrication process to minimize the increase of the production cost.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A lateral double diffused metal oxide semiconductor device comprising:
a substrate of a first conductive type;
a deep well region of a second conductive type, configured in the substrate;
two body regions of the first conductive type, configured in the deep well region;
at least one body connection region of the first conductive type, configured in the deep well region for connecting the two body regions;
two source regions of the second conductive type, wherein each of the two source regions is respectively configured in each of the two body regions;
a drain region of the second conductive type, configured in the deep well region between the two source regions;
a channel region, configured in a part of the two body regions between the two source regions and the drain region; and
a gate electrode, configured on the deep well region between the two source regions and the drain region, wherein the gate electrode covers the channel region.

2. The lateral double diffused metal oxide semiconductor device of claim 1, wherein a dopant concentration of the body connection region is equal or greater than a dopant concentration of the two body regions.

3. The lateral double diffused metal oxide semiconductor device of claim 1 further comprising a graded region of the second conductive type surrounding a peripheral of the drain region.

4. The lateral double diffused metal oxide semiconductor device of claim 1, wherein each of the two body regions comprises a first endpoint and a second endpoint, and the at least one body connection region connects the first endpoint of each of the two body regions.

5. The lateral double diffused metal oxide semiconductor device of claim 1, wherein the at least one body connection region comprises two body connections regions, and one of the two body connection regions connects a first endpoint of each of the two body regions and another of the two body connection regions connects a second endpoint of each of the two body regions.

6. The lateral double diffused metal oxide semiconductor device of claim 1, wherein the gate electrode is horseshoe shape or closed ring shape.

7. The lateral double diffused metal oxide semiconductor device of claim 1, wherein the first conductive type is a P conductive type, and the second conductive type is an N conductive type.

8. The lateral double diffused metal oxide semiconductor device of claim 1, wherein the first conductive type is an N conductive type, and the second conductive type is a P conductive type.

9. The lateral double diffused metal oxide semiconductor device of claim 1 further comprising:
a well region of the first conductive type, configured at a peripheral of the deep well region; and
a doped region of the first conductive type, configured in the well region to serve as a protection ring.

10. A lateral double diffused metal oxide semiconductor device comprising:
a substrate of a first conductive type;
a deep well region of a second conductive type, configured in the substrate;
a well region of the first conductive type, configured at a peripheral of the deep well region;
a doped region of the first conductive type, configured in the well region to serve as a protection ring;
a plurality of body regions of the first conductive type, configured in the deep well region;
a plurality of body connection region of the first conductive type, configured in the deep well region for connecting the plurality of the body regions;
a plurality of source regions of the second conductive type, wherein each of the plurality of the source regions is configured in each of the plurality of the body regions;
a plurality of drain regions of the second conductive type, configured in the deep well region between the plurality of the source regions;
a plurality of channel regions, wherein each of the plurality of the channel regions is configured in a part of each of the plurality of the body regions between each source region of the plurality of the source regions and each neighboring drain region of the plurality of the drain regions; and
a plurality of gate electrodes, wherein each of the plurality of the gate electrodes is configured on the deep well region between any two neighboring source regions of the plurality of the source regions and the drain region of the plurality of the drain regions in between the any two neighboring source regions, and the plurality of the gate electrodes covers the plurality of the channel regions between the any two neighboring source regions of the plurality of the source regions.

11. The lateral double diffused metal oxide semiconductor device of claim 10, wherein
the plurality of the body regions comprises a first body region, a second body region and a third body region, and the second body region is disposed between the first body region and the third body region, wherein each of the plurality of the body regions comprises a first endpoint, an intermediate section and a second endpoint, and the intermediate section of each of the plurality of the body regions is configured between the first endpoint and the second end point of each of the plurality of the body regions; and
the plurality of the body connection regions comprises at least a first body connection region and at least a second body region, wherein the at least first body connection region connects the first body region with the second body region, and the at least second body connection region connects the second body region with the third body region.

12. The lateral double diffused metal oxide semiconductor device of claim 11, wherein the at least first body connection region connects any one, any two or all of the first endpoints, the intermediate sections and the second endpoints of the first body region and the second body region, and the at least second body connection region connects any one, any two or all of the first endpoints, the intermediate sections and the second endpoints of the second body region and the third body region.

13. The lateral double diffused metal oxide semiconductor device of claim 10, wherein a dopant concentration of the plurality of the body connection regions is equal or greater than a dopant concentration of the plurality of the body regions.

14. The lateral double diffused metal oxide semiconductor device of claim 10 further comprising a plurality of graded regions of the second conductive type, wherein each of the plurality of the graded regions surrounds a peripheral of each of the plurality of the drain regions.

15. The lateral double diffused metal oxide semiconductor device of claim 10, wherein each of the plurality of the gate electrodes is closed ring shape or horseshoe shape.

16. The lateral double diffused metal oxide semiconductor device of claim 10, wherein the first conductive type is a P conductive type, and the second conductive type is an N conductive type.

17. The lateral double diffused metal oxide semiconductor device of claim 1, wherein the first conductive type is an N conductive type, and the second conductive type is a P conductive type.
